(19) United States
(12) Patent Application Publication
(10) Pub. No.: US 2012/0086003 A1
(43) Pub. Date: Apr. 12, 2012

(54) SEMICONDUCTOR DEVICE AND TEST SYSTEM FOR THE SEMICONDUCTOR DEVICE

(76) Inventor: SUNG-KYU PARK, Hwaseong-si (KR)

(21) Appl. No.: 13/243,299

(22) Filed: Sep. 23, 2011

(30) Foreign Application Priority Data
Oct. 6, 2010 (KR) 10-2010-0097420

(51) Int. Cl. H01L 23/58; H01L 23/498

(52) U.S. Cl. 257/48; 257/774; 257/737; 257/E23.067; 257/E23.068; 257/E23.002

(57) ABSTRACT

A semiconductor package including a stress mitigation unit that mitigates stress to the semiconductor chip. The semiconductor package includes a substrate, a semiconductor chip on the substrate, an encapsulation member formed on the substrate and covering the first semiconductor chip, and the stress mitigation unit mitigating stress from a circumference of the first semiconductor chip to the first semiconductor chip. The stress mitigation unit includes at least one groove formed in the encapsulation member.

### CROSS-REFERENCE TO RELATED APPLICATION

This application claims the benefit of Korean Patent Application No. 10-2010-0097420, filed on Oct. 6, 2010, in the Korean Intellectual Property Office, the disclosure of which is incorporated herein in its entirety by reference.

### BACKGROUND

The inventive concept relates to a semiconductor device and a test system for the semiconductor device, and more particularly, to a semiconductor device including a stress mitigation unit for protecting a semiconductor chip by mitigating stress to the semiconductor chip.

In general, semiconductor chips are formed on a wafer via a semiconductor fabricating procedure, are detached from the wafer as semiconductor devices, and then fabricated as semiconductor packages. A semiconductor package, for example, includes a substrate, a semiconductor chip on the substrate, and an encapsulation member protecting the semiconductor chip by covering the semiconductor chip. Due to requirements for faster operation and higher density implementation of semiconductor packages, a Package On Package (POP)-type semiconductor package formed by stacking a plurality of semiconductor packages has been used.

### SUMMARY

The embodiments of the inventive concept provide a semiconductor device having a configuration for protecting parts of a semiconductor package, including a semiconductor chip, bumps, solder balls, or the like, by mitigating stress due to external forces applied to a semiconductor package, or stress due to imbalance between internal thermal expansion and internal thermal contraction.

According to an embodiment of the inventive concept, there is provided a semiconductor device including a first substrate, a first semiconductor chip on the first substrate, an encapsulation member on the first substrate and covering the first semiconductor chip, and a stress mitigation unit mitigating stress from a circumference of the first semiconductor chip to the first semiconductor chip.

The stress mitigation unit may include at least one groove formed in the encapsulation member, and the groove may penetrate through the encapsulation member from a surface of the encapsulation member to the first substrate, or may partially penetrate the encapsulation member from a surface of the encapsulation member to an upper portion of the encapsulation member. Also, the groove may include a slope, wherein a diameter of the groove from a surface of the encapsulation member decreases in a direction toward the first substrate.

The groove may be formed over the first substrate, except for portions over an upper surface of the first semiconductor chip, and may be spaced apart from and surrounding the first semiconductor chip.

The groove may be formed in a side surface of the encapsulation member, may be formed at an interface between the encapsulation member and the first substrate, or may be entirely formed in an inner portion of the encapsulation member.

A filling material may fill in the groove.

The semiconductor device may further include a second substrate electrically contacting the first substrate, and a second semiconductor chip formed on the second substrate.

A Through Mold Via (TMV) may be formed in the encapsulation member to electrically connect the first substrate and the second substrate.

The encapsulation member may include an inner encapsulation member for protecting the first semiconductor chip by covering the first semiconductor chip, and an inner substrate whereon the first semiconductor chip is formed, or an inner semiconductor chip may be formed in the first substrate.

The stress mitigation unit may include one or more blocking protrusions formed around the first semiconductor chip, and/or may include one or more blocking walls that protect the first semiconductor chip by surrounding all or part of the first semiconductor chip.

The stress mitigation unit may include one or more grooves formed in the first substrate.

According to another aspect of the inventive concept, there is provided a test system of a semiconductor device including a substrate, a semiconductor chip on the substrate, an encapsulation member formed on the substrate and covering the semiconductor chip, and a stress mitigation unit formed in the encapsulation member and mitigating stress from a circumference of the first semiconductor chip to the first semiconductor chip, the test system comprising a testing device detecting a deformation of the stress mitigation unit.

According to another aspect of the inventive concept, there is provided a semiconductor device including a first substrate, a first semiconductor chip, wherein one or more bumps for contacting the first substrate are formed on a bottom surface of the first semiconductor chip, an encapsulation member formed on the first substrate and covering the first semiconductor chip, and a stress mitigation unit formed in the encapsulation member and mitigating stress from a circumference of the first semiconductor chip to a contact area between the one or more bumps and the first substrate.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view illustrating a status in which an external bend force is applied to a semiconductor package according to an embodiment of the inventive concept;

FIG. 2 is a cross-sectional view illustrating a status in which an external backward-bend force is applied to the semiconductor package of FIG. 1;

FIG. 3 is a cross-sectional view the semiconductor package in FIG. 1, in accordance with an embodiment of the inventive concept;

FIG. 4 is a cross-sectional view of a stack of a first semiconductor package and a second semiconductor package 3, in which thermal expansion and contraction forces are exerted;

FIG. 5 is a cross-sectional view of a semiconductor package according to another embodiment of the inventive concept, in which a relative expansion force and a relative contraction force are exerted;

FIG. 6 is a cross-sectional view of a semiconductor package according to another embodiment of the inventive concept;

FIG. 7 is a cross-sectional view of a semiconductor package according to another embodiment of the inventive concept;

FIG. 8 is a magnified cross-sectional view of a groove in a semiconductor package according to another embodiment of the inventive concept;

FIG. 9 is a magnified cross-sectional view of a groove in a semiconductor package, in accordance with an embodiment of the inventive concept;

FIG. 10 is a magnified cross-sectional view of a groove in a semiconductor package, in accordance with an embodiment of the inventive concept;

FIG. 11 is a cross-sectional view of a semiconductor package according to another embodiment of the inventive concept;

FIG. 12 is a plane view of a groove in a semiconductor package according to another embodiment of the inventive concept;

FIG. 13 is a plan view of a groove, in accordance with an embodiment of the inventive concept;

FIG. 14 is a cross-sectional view of a semiconductor package according to another embodiment of the inventive concept;

FIG. 15 is a cross-sectional view of a semiconductor package according to another embodiment of the inventive concept;

FIG. 16 is a cross-sectional view of a semiconductor package according to another embodiment of the inventive concept;

FIG. 17 is a cross-sectional view of a semiconductor package according to another embodiment of the inventive concept;

FIG. 18 is a cross-sectional view of a semiconductor package according to another embodiment of the inventive concept;

FIG. 19 is a cross-sectional view of a semiconductor package according to another embodiment of the inventive concept;

FIG. 20 is a magnified cross-sectional view of a semiconductor package according to another embodiment of the inventive concept;

FIG. 21 is a cross-sectional view illustrating a status in which an external bend force is applied to a semiconductor package according to another embodiment of the inventive concept;

FIG. 22 is a cross-sectional view illustrating a status in which an external backward-bend force is applied to the semiconductor package of FIG. 21;

FIG. 23 is a cross-sectional view of a semiconductor package according to another embodiment of the inventive concept;

FIG. 24 is a cross-sectional view of a semiconductor package according to another embodiment of the inventive concept;

FIG. 25 is a cross-sectional view of a semiconductor package according to another embodiment of the inventive concept;

FIG. 26 is a cross-sectional view of a semiconductor package according to another embodiment of the inventive concept;

FIG. 27 is a cross-sectional view of a semiconductor package according to another embodiment of the inventive concept;

FIG. 28 is a cross-sectional view of a semiconductor package according to another embodiment of the inventive concept;

FIG. 29 is a cross-sectional view of a semiconductor package according to another embodiment of the inventive concept;

FIG. 30 is a magnified cross-sectional view of a test system of a semiconductor package, according to another embodiment of the inventive concept; and

FIG. 31 is a magnified cross-sectional view of a test system of a semiconductor package, according to another embodiment of the inventive concept.

### DETAILED DESCRIPTION OF THE EMBODIMENTS

The embodiments of the inventive concept will now be described more fully with reference to the accompanying drawings, in which exemplary embodiments of the inventive concept are shown. The inventive concept may, however, be embodied in many different forms and should not be construed as being limited to the embodiments set forth herein. In the drawings, various components and regions are schematic, and thus are not limited to relative sizes or gaps shown in the drawings. Like reference numerals in the drawings may denote like elements.

It will be understood that when an element or layer is referred to as being “on,” “connected to” or “coupled to” another element or layer, it can be directly on, connected or coupled to the other element or layer or intervening elements or layers may be present.

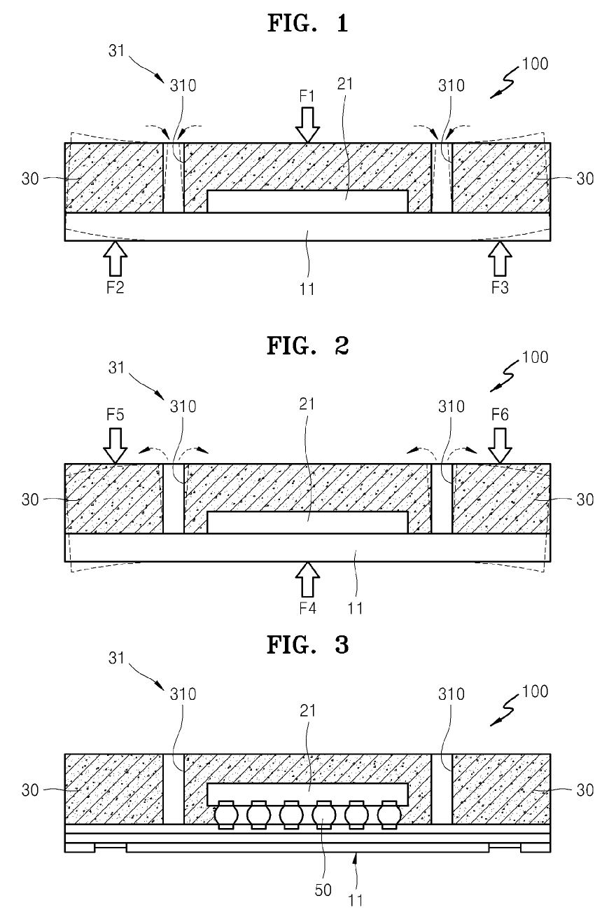

FIG. 1 is a cross-sectional view illustrating a status in which an external bend force is applied to a semiconductor package according to an embodiment of the inventive concept. FIG. 2 is a cross-sectional view illustrating a status in which an external backward-bend force is applied to the semiconductor package of FIG. 1.

As illustrated in FIGS. 1 and 2, a semiconductor device includes a first semiconductor package 100 including a first substrate 11, a first semiconductor chip 21, and an encapsulation member 30. A line (not shown) capable of delivering an electrical signal is formed on the first substrate 11. The first semiconductor chip 21 is on the first substrate 11, and the first substrate 11 is electrically connected with the first semiconductor chip 21 so that the first substrate 11 may deliver an electrical signal generated by the first semiconductor chip 21 to an outer device.

According to an embodiment, the first semiconductor chip 21 is fabricated via a semiconductor procedure such that the first semiconductor chip 21 is disposed on the first substrate 11, and is electrically connected with the first substrate 11 by direct contact with the first substrate 111.

The encapsulation member 30 electrically protects the first semiconductor chip 21 by covering the first semiconductor chip 21 so as to maintain characteristics of the electrical signal generated by the first semiconductor chip 21. The encapsulation member 30 also physically protects the first semiconductor chip 21 from various external forces or foreign substances. According to an embodiment, the encapsulation member 30 includes a thermocurable resin that is an insulating material, that is capable of being thermally formed, and that is hardened after being thermally formed. Accordingly, the encapsulation member firmly protects the first semiconductor chip 21.

As illustrated in FIGS. 1 and 2, the encapsulation member 30 has a stress mitigation unit 31 formed on its top surface. The stress mitigation unit 31 protects parts, including, for example, the first semiconductor chip 21, bumps, solder balls, or the like, by mitigating stress due to one or more external forces F1 through F6 applied to a semiconductor package, or stress due to imbalance between internal thermal expansion and internal thermal contraction, which is described further below.

As illustrated in FIGS. 1 and 2, the stress mitigation unit 31 includes one or more grooves 310 recessed in the encapsulation member 30.

The grooves 310 are formed by using one of various methods in which a portion of the encapsulation member 30 is cut by using a mechanical equipment, the encapsulation member 30 is partially etched, a laser hole operation is performed on the encapsulation member 30 by irradiating a laser beam onto the encapsulation member 30, or the encapsulation member 30 is melted by heat.

As a result the processes for forming the groove 310 in the encapsulation member 30, portions of the encapsulation member having the groove 310 formed therein have a reduced thickness, volume and/or size, compared to those portions not having the grooves 310 formed therein. As a result, when deformation occurs due to external or thermal forces, the portions including the groove 310 are more flexible to the deformation than the portions without the grooves 310. As shown by the dashed arrows and dashed lines in FIGS. 1 and 2, deformation occurs at the grooves 310 in response to stresses applied toward the first semiconductor chip 21.

For example, referring to FIG. 1, when bend deformation as denoted by the dashed lines in FIG. 1 occurs in the first semiconductor package 100 due to the external forces F1, F2, and F3, since entrances of the grooves 310 narrow, it is possible to mitigate stresses that are applied to the first semiconductor chip 21 due to the external forces F1, F2, and F3. As a result, by mitigating the stresses, damage to the first semiconductor package 100 due to external forces may be prevented. In other words, according to an embodiment of the inventive concept, bend deformation due to the external forces F1, F2, and F3 is actively induced to mainly occur in the grooves 310 so that other parts of the semiconductor package are not altered by the stress. Thus, by inducing deformation to occur in the grooves 310, it is possible to prevent parts, such as the first semiconductor chip 21 or a signal connecting member such as a bump 50 (refer to FIG. 3), from deforming. Therefore, as described above, the encapsulation member 30 is made more flexible to various external forces or shocks by using the grooves 310, and deformation is induced in weaker parts in the groove 310, so as to prevent other parts from deforming.

Referring to FIG. 2, backward-bend as denoted by the dashed lines in FIG. 2 occurs in the first semiconductor package 100 due to the external forces F4, F5, and F6, which are in a reverse direction with respect to the external forces F1, F2, and F3. As shown in FIG. 2, entrances of the grooves 310 widen, so as to prevent other parts of semiconductor package from deforming due to the external forces F4, F5, and F6.

The aforementioned external forces F1 through F6 are to illustrate external forces, it is to be understood that various external forces other than what is illustrated, may be applied to the semiconductor package.

The embodiments of the inventive concept may apply to various physical forces or shocks, loads, and fatigue loads, which may affect a semiconductor package in a rough environment.

Since materials of the first substrate 11, the first semiconductor chip 21, and the encapsulation member 30 are different from each other, thermal expansion coefficients thereof may be different, causing thermally induced stresses, and damage or detachment of elements of the semiconductor package. However, in the semiconductor packages according to embodiments of the present inventive concept, deformation due to the thermal expansion and contraction forces is induced in the grooves 310.

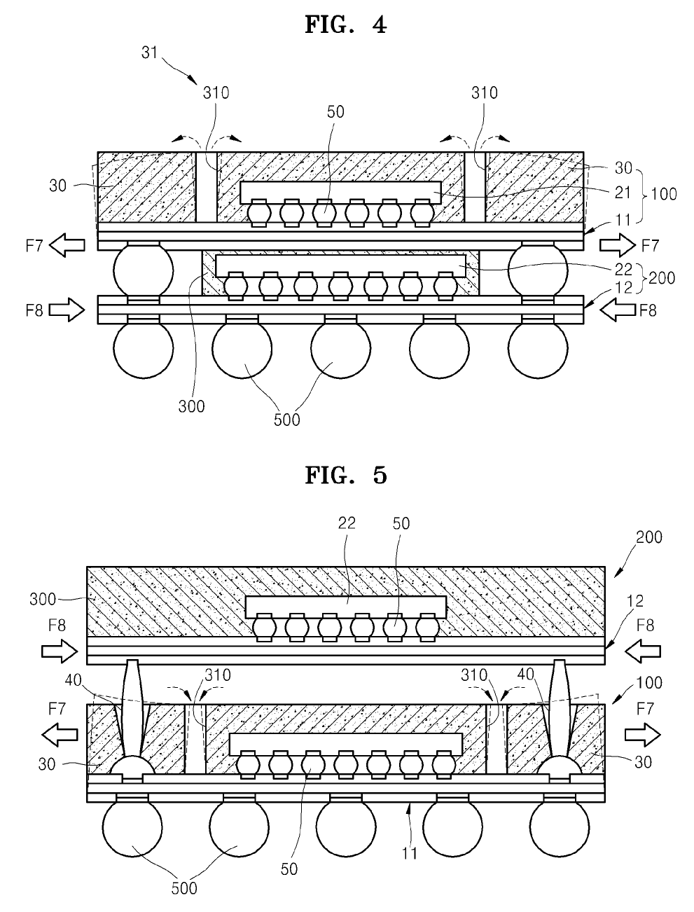

The expansion and contraction forces are further described below with reference to FIGS. 4 and 5.

Accordingly, the semiconductor packages in accordance with embodiments of the inventive concept, are resistant to various external forces or shocks so that durability of a resulting product increases, and a normal operation of a product may be guaranteed by the protection offered by the embodiments of the inventive concept.

FIG. 3 is a cross-sectional view of the semiconductor package in FIG. 1, in accordance with an embodiment of the inventive concept. FIG. 4 is a cross-sectional view of a stack of the first semiconductor package 100 and a second semiconductor package 200, in which thermal expansion and contraction forces are exerted.

Due to requirements for faster operation and higher density implementation of semiconductor packages, a Package On Package (POP)-type semiconductor package formed by stacking a plurality of semiconductor packages has been used, and one or more embodiments of the inventive concept may be applied to a POP-type semiconductor package. As illustrated in FIG. 4, a semiconductor package according to an embodiment of the present inventive concept has a POP-type structure in which the second semiconductor package 200 is stacked below the first semiconductor package 100.

As illustrated in FIGS. 3 and 4, the first semiconductor package 100 includes the first substrate 11, the first semiconductor chip 21 on the first substrate 11, and the encapsulation member 30 protecting the first semiconductor chip 21 by covering the first semiconductor chip 21. The second semiconductor package 200 is stacked under the first semiconductor package 100, and includes a second substrate 12 and a second semiconductor chip 22 on the second substrate 12. A second encapsulation member 300 protects the second semiconductor chip 22 by covering the second semiconductor chip 22. In accordance with an embodiment of the inventive concept, one or more grooves 310 are arranged in sides of the first semiconductor package 100 so as to induce deformation.

As illustrated in FIGS. 3 and 4, bumps 50 that are a type of the signal connecting member are arranged between the first substrate 11 and the first semiconductor chip 21. The bumps 50 contact terminals of the first substrate 11 for a delivery of an electrical signal. Accordingly, the grooves 310 of the semiconductor package function to assure the contact of the bumps 50 with the terminals of the first substrate 11. As illustrated in FIG. 4, in the POP-type semiconductor package in which the second semiconductor package 200 is stacked below the first semiconductor package 100, thermal expansion coefficients between the first semiconductor package 100 and the second semiconductor package 200 are different so that, when a relative expansion force F7 and a relative contraction force F8 occur in a high-temperature thermal environment, including a solder ball melting operation or the like, the POP-type semiconductor package is bent.

Thus, as illustrated in FIG. 4, in a case where the first semiconductor package 100 is bent and deformed due to the relative expansion force F7 and the relative contraction force F8, as denoted by the dashed lines in FIG. 4, entrances of the grooves 310 widen so that deformation of the encapsulation member 30 due to the relative expansion force F7 and the relative contraction force F8 is facilitated. Accordingly, by making the encapsulation member 30 more flexible, total or partial damage to the first semiconductor package 100 or the second semiconductor package 200 due to thermal deformation may be prevented. According to embodiments of the inventive concept, it is possible to actively induce the bend deformation due to the relative expansion force F7 and the relative contraction force F8 to mainly occur in the grooves 310 that may be formed at relatively less important parts of the semiconductor package, which do not include essential components. Thus, as described above, the encapsulation member 30 is made more flexible by the grooves 310, so as to be less affected by various thermal deformations. Deformation of weaker parts in the grooves 310 is induced so as to maximally prevent essential parts from deforming.

FIG. 5 is a cross-sectional view of a semiconductor package according to another embodiment of the inventive concept, in which a relative expansion force and a relative contraction force are exerted. As illustrated in FIG. 5, the semiconductor package according to the embodiment illustrated in FIG. 5 includes a POP structure in which a second semiconductor package 200 is stacked on a first semiconductor package 100. The semiconductor package of FIG. 4 has a POP structure in which the second semiconductor package 200 is stacked below the first semiconductor package 100, whereas the semiconductor package of FIG. 5 has a POP structure in which the second semiconductor package 200 is stacked on the first semiconductor package 100. Referring to FIG. 5, a Through Mold Via (TMV) 40 formed through an encapsulation member 30 electrically connects a first substrate 11 and a second substrate 12.

Unlike FIG. 4, in FIG. 5, when backward-bend deformation as denoted by the dashed lines occurs in the first semiconductor package 100 due to a relative expansion force F7 and a relative contraction force F8, entrances of grooves 310 narrow so that deformation of the encapsulation member 30 due to the relative expansion force F7 and the relative contraction force F8 is further facilitated. Accordingly, by making the encapsulation member 30 more flexible, total or partial damage to the first semiconductor package 100 or the second semiconductor package 200 due to thermal deformation may be prevented.

In accordance with an embodiment of the inventive concept, it is possible to actively induce the backward-bend deformation due to the relative expansion force F7 and the relative contraction force F8 to mainly occur in the grooves 310. That is, by inducing the deformation to occur in the grooves 310, it is possible to prevent essential components, including, for example, a first semiconductor chip 21, or a signal connecting member such as bumps 50 or solder balls 500, from deforming. Thus, it is possible, through use of the grooves 310, to make the encapsulation member 30 more flexible so as to be less affected by various thermal deformations, and to induce deformation of weaker parts in the grooves 310.

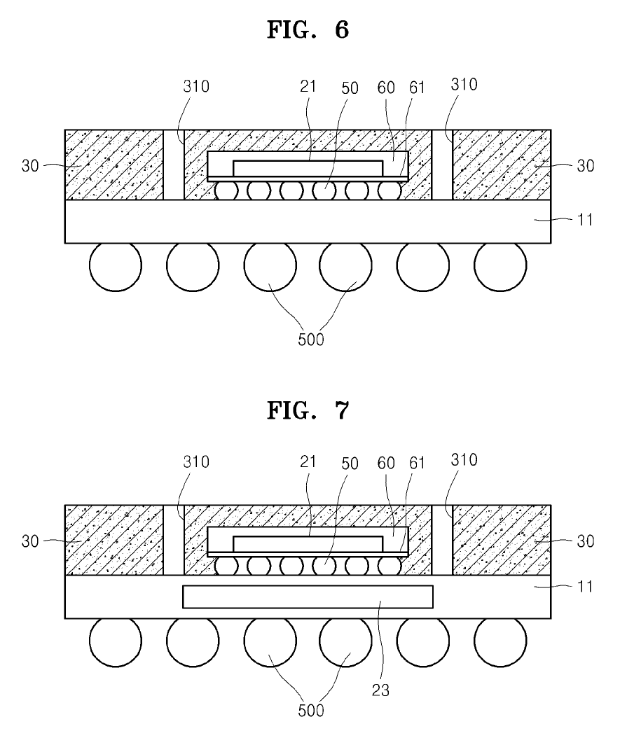

FIGS. 6 and 7 are cross-sectional views of semiconductor packages according to other embodiments of the inventive concept.

As illustrated in FIGS. 6 and 7, an encapsulation member 30 further includes an inner encapsulation member 60 that protects a first semiconductor chip 21 by covering the first semiconductor chip 21, and an inner substrate 61 whereon the first semiconductor chip 21 is formed.

A structure of the semiconductor package, in which the encapsulation member 30 further includes the inner encapsulation member 60 and the inner substrate 61, is referred to as a Package In Package (PIP)-type semiconductor package.

That is, one or more embodiments of the inventive concept may be applied to not only a POP-type semiconductor package but also may be applied to a PIP-type semiconductor package.

As an example of the PIP-type semiconductor package, as illustrated in FIG. 7, an inner semiconductor chip 23 is arranged in a first substrate 11.

Thus, although a relative expansion force and a relative contraction force due to external forces, shocks, or thermal expansion between the inner encapsulation member 60, the inner substrate 61, the inner semiconductor chip 23, the encapsulation member 30, the first substrate 11, and the first semiconductor chip 21 of FIGS. 6 and 7 are exerted such that deformation occurs, grooves 310 sufficiently localize the deformation to the area of the grooves 310, and away from essential components.

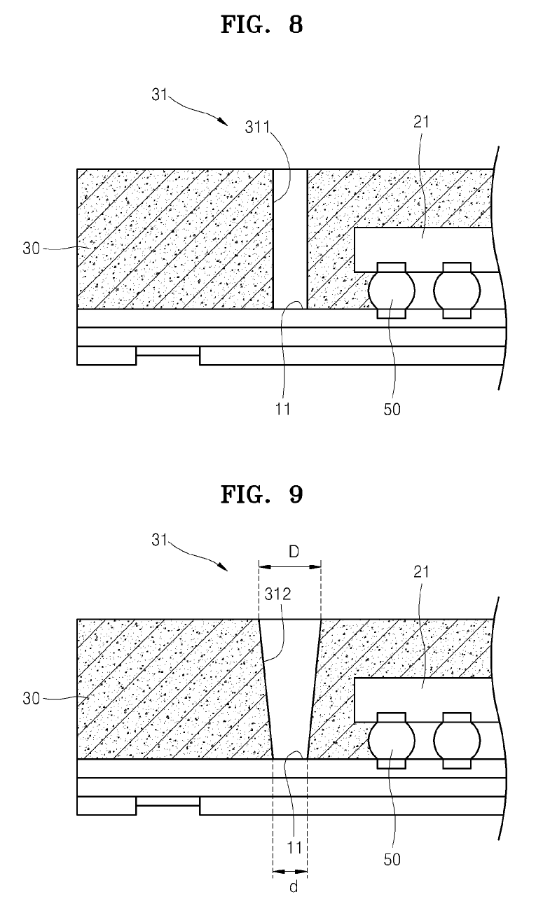

FIGS. 8-10 are magnified cross-sectional views of grooves in semiconductor packages according to embodiments of the inventive concept.

As illustrated in FIGS. 8 through 10, a shape of the groove according to the embodiments may vary.

First, as illustrated in FIG. 8, the groove 311 has a through-groove shape penetrating from a surface of an encapsulation member 30 to a first substrate 11.

As illustrated in FIG. 9, a groove 312 has a slope groove shape of which a diameter D at a surface of an encapsulation member 30 is larger and gradually decreases to a diameter d as the groove approaches the first substrate 11. The groove 312 having an entrance diameter D that is larger than the diameter d adjacent to the first substrate 11, may induce larger deformations.

Since deformation is usually greater at an entrance of the groove 312, the entrance diameter D of the groove 312 is greater than the diameter d adjacent the first substrate 11, as illustrated in FIG. 9.

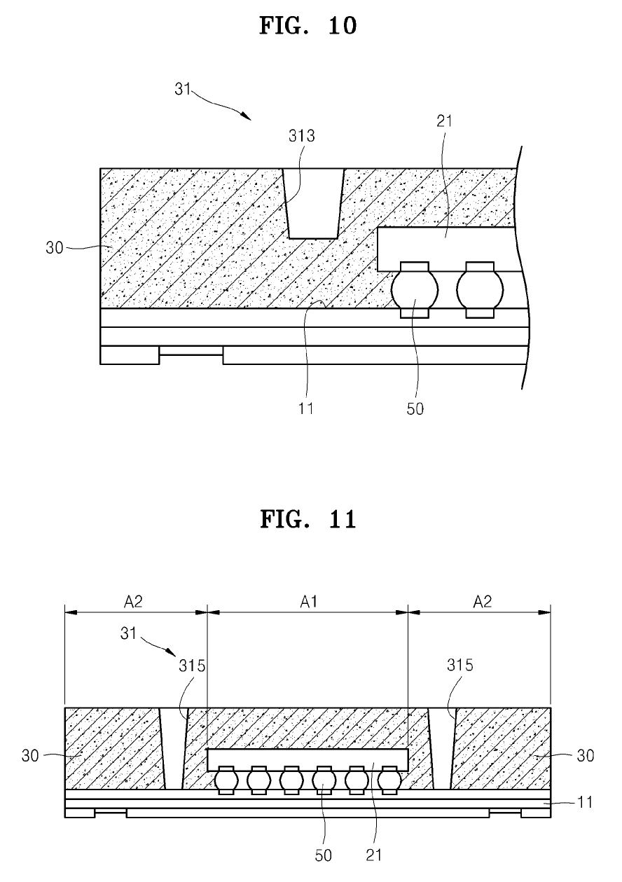

As illustrated in FIG. 10, a groove 313 may be a partial groove that does not completely penetrate the encapsulation member from a surface of the encapsulation member 30 to the first substrate 11 but, instead, is formed only in an upper portion of the encapsulation member 30. Since the first substrate 11 remains covered under the groove 313, the configuration of the groove 313 in FIG. 10 prevents various foreign substances from contaminating the first substrate 11.

FIG. 11 is a cross-sectional view of a semiconductor package according to another embodiment of the inventive concept. As illustrated in FIG. 11, grooves 315 are not be formed in an upper region A1 of the first substrate 11. As shown in FIG. 11, the grooves 315 are formed in upper regions A2 of the first substrate 11, and have a slope groove shape.

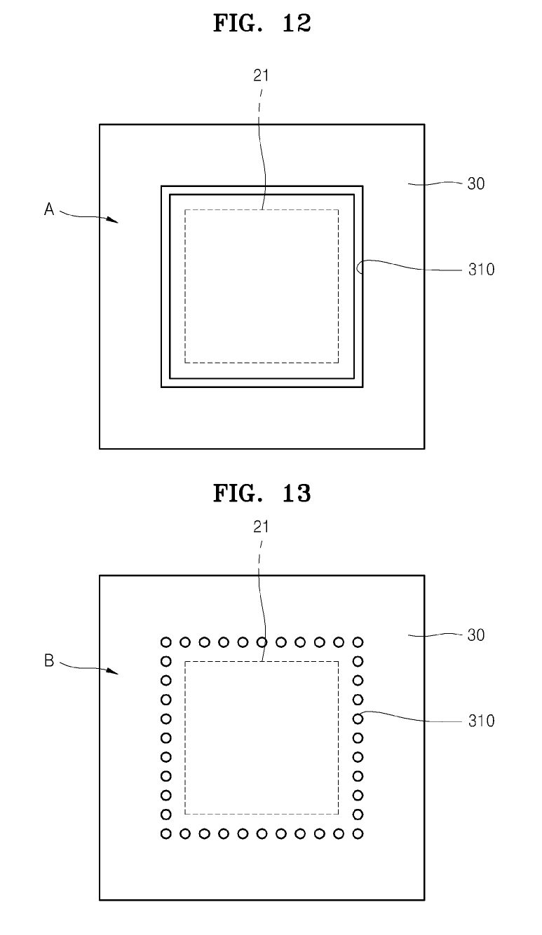

FIGS. 12 and 13 are plan views of grooves 310 in semiconductor packages according to embodiments of the inventive concept. As illustrated in FIG. 12, the groove 310 may have a connection line shape A that is separate from a first semiconductor chip 21 and is formed along a circumference/perimeter of the first semiconductor chip 21.

As illustrated in FIG. 13, the grooves 310 may comprise a plurality of dot shaped grooves B that are separate from a first semiconductor chip 21 and are formed along a circumference/perimeter of the first semiconductor chip 21. Thus, as illustrated in FIGS. 12 and 13, since the grooves 310 are separate from the first semiconductor chip 21 and surround the first semiconductor chip 21, it is possible to prevent deformation of the first semiconductor chip 21, so that relatively important parts, including, for example, the first semiconductor chip 21, bumps, solder balls, or the like, may be protected.

As alternatives to the connection line shape A and the dot shape B, the grooves 310 may have various shapes including, for example, a polygonal shape, a honeycomb shape, a diagonal shape, an X-shape, a circular shape, an oval shape, a U-shape, an L-shape, a zigzag shape, a jagged shape, a wave shape, a concentric circular shape, a swirl shape, a maze shape, or the like. The various shapes of the groove 310 may be optimized and designed according to characteristics of the semiconductor package, which include, for example, a size, a thickness, a degree of thermal expansion, a material, thermal environment condition, a type or direction of an external force, or the like.

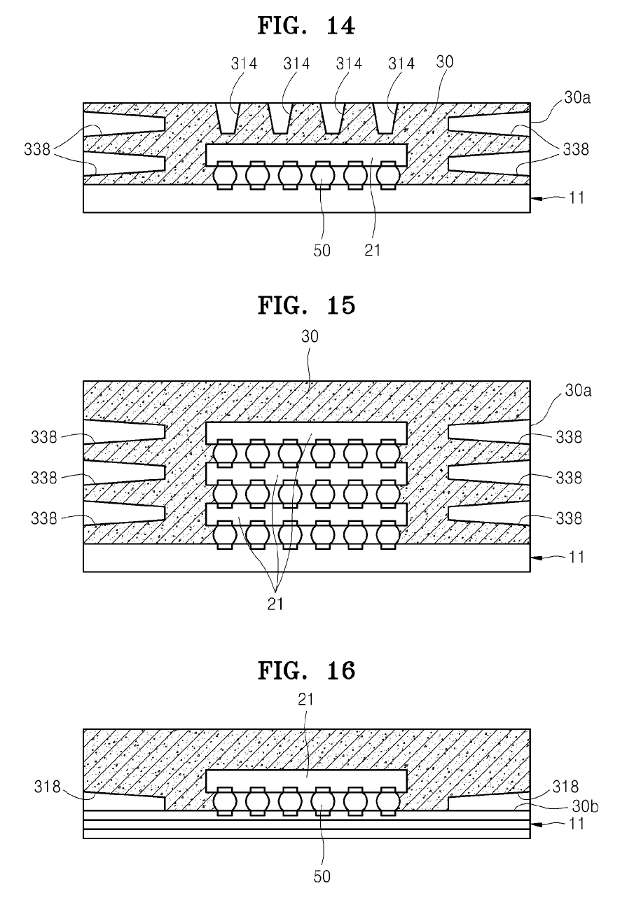

FIGS. 14 and 15 are each cross-sectional views of a semiconductor package according to embodiments of the inventive concept. As illustrated in FIG. 14, grooves 338 are side-surface type grooves that are formed from side surfaces 30a of an encapsulation member 30.

The grooves 338 may be formed together with grooves 314 that are formed in a top surface of an encapsulation member 30. The grooves 314 are partial grooves, like the grooves 313.

As illustrated in FIG. 15, in a case where two or more first semiconductor chips 21 are vertically layered, the grooves 338, which are the side-surface type grooves, may be more efficient given the size and space constraints of the encapsulation layer 30.

Like the grooves described in connection with the previous embodiments, the side-surface type grooves 338 may sufficiently induce and/or localize deformation in response to a relative side-surface expansion force or a relative side-surface contraction force exerted due to a side-surface external force, a side-surface shock, or thermal expansion of the encapsulation member 30.

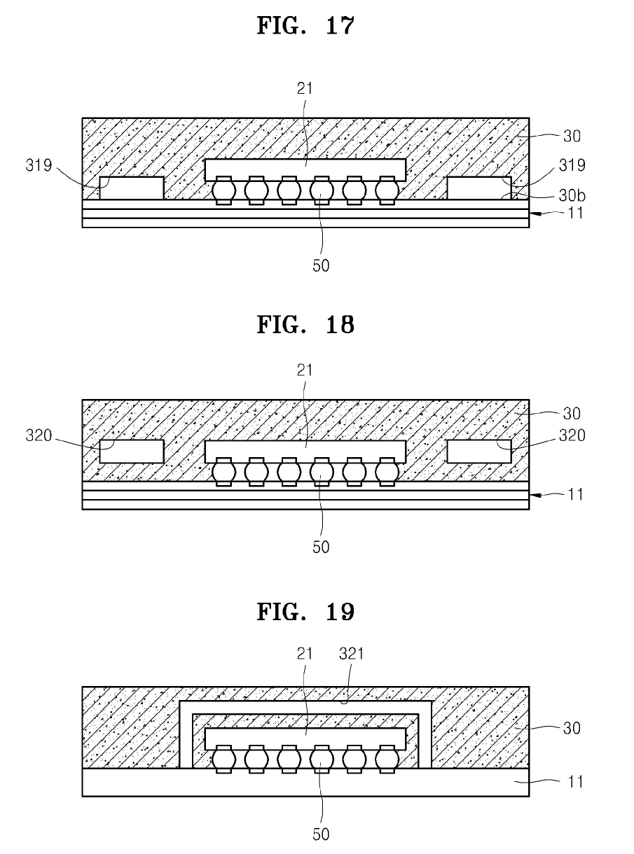

FIGS. 16 through 18 are each cross-sectional views of a semiconductor package according to embodiments of the inventive concept. As illustrated in FIG. 16, a groove 318 is an interface type groove that is formed at an interface 30b between an encapsulation member 30 and a first substrate 11. By decreasing a contact area between the encapsulation member 30 and the first substrate 11, damage to and detachment of the interface 30b due to thermal expansion may be prevented. Also, as illustrated in FIG. 17, a groove 319 is an inner interface type groove that is formed at an interface 30b between an encapsulation member 30 and the first substrate 11. The inner interface type groove 319 does not include an entrance at a side or top surface of the encapsulation member 30. As illustrated in FIG. 18, a groove 320 is an inner type groove that is formed as a space within an encapsulation member 30, without an entrance at a side surface or top surface of the encapsulation member 30, and not formed at the interface 30b.

In order to form the interface type groove 318, the inner interface type groove 319, and the inner type groove 320, one of various methods may be used, including, for example, a double injection mold method, by which a groove is first formed using a first injection mold and then an opening is sealed using a second injection mold. The inner interface type groove 319 and the inner type groove 320 may make the encapsulation member 30 more flexible, and likely to be deformed due to an external force, or expansion and contraction forces, and simultaneously prevent inner contamination by blocking penetration of foreign substances.

FIG. 19 is a cross-sectional view of a semiconductor package according to another embodiment of the inventive concept. Here, a groove 321 is an inner type groove that surrounds a first semiconductor chip 21 in a space in an encapsulation member 30. The groove 321 prevents stresses generated around the first semiconductor chip 21 from reaching the first semiconductor chip 21, so that the groove 321 protects the first semiconductor chip 21, bumps 50, solder balls, or the like.

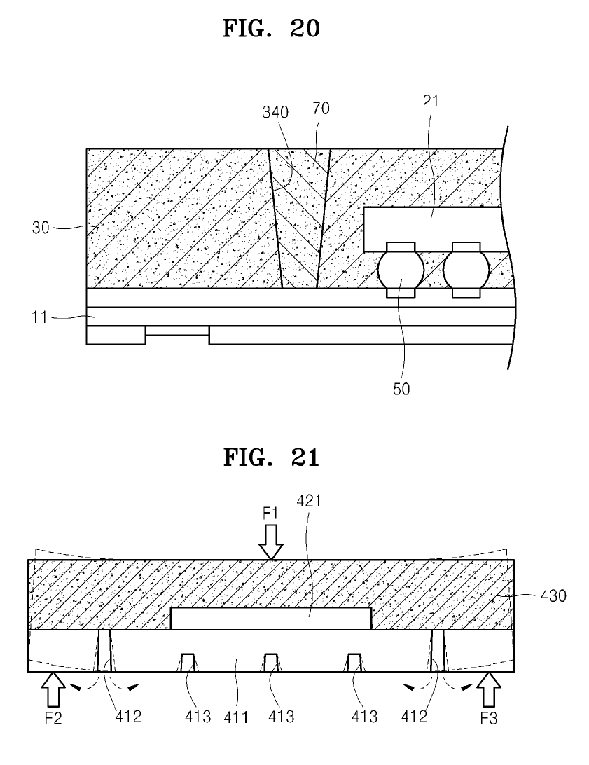

FIG. 20 is a magnified cross-sectional view of a semiconductor package according to another embodiment of the inventive concept. As illustrated in FIG. 20, a filling material 70 having elasticity and including, for example, a rubber, a resin, urethane, silicone, a polymer material, plastic, STYROFOAM, or the like, fills in a groove 340 that is formed in the encapsulation member 30. Thus, the filling material 70 prevents excessive deformation of the groove 340.

Also, the filling material 70 blocks, for example, foreign substances or dust from entering the groove 340.

The filling material 70 may be used to measure a level of deformation by determining that deformation causing a narrowed entrance of the groove 340 has occurred when the filling material 70 projects from a surface of the encapsulation member 30, or by determining that deformation causing a widened entrance of the groove 340 has occurred when the filling material 70 is recessed from the surface of the encapsulation member 30.

The filling material 70 filling the groove 340 may include, for example, steel materials, such as metal, ceramic, engineering plastic, or the like, which are rigid, instead of elastic. In this case, stress to a first semiconductor chip 21 may be blocked by the filling material 70.

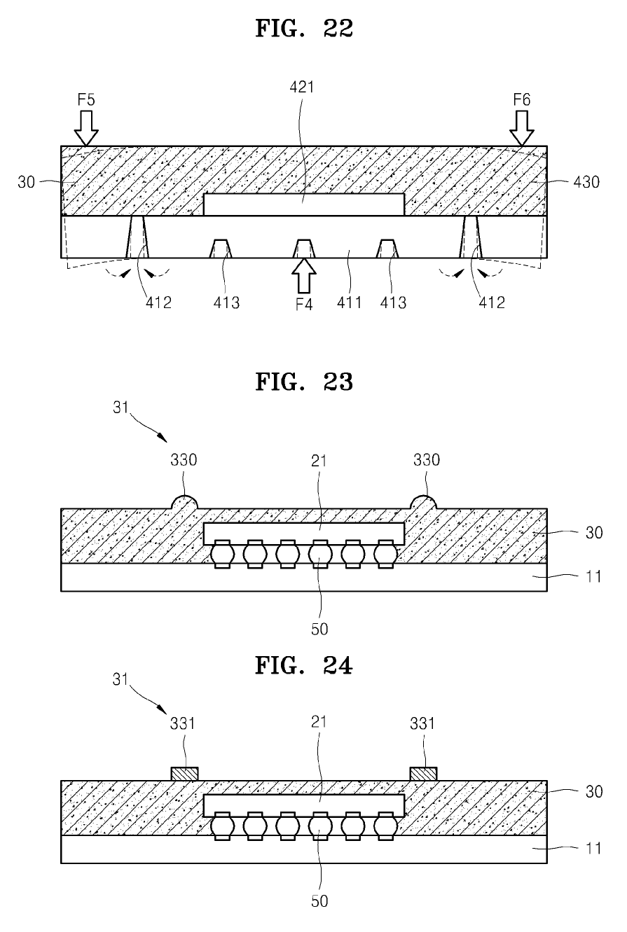

FIG. 21 is a cross-sectional view illustrating a status in which an external bend force is applied to a semiconductor package according to another embodiment of the inventive concept. FIG. 22 is a cross-sectional view illustrating a status in which an external backward-bend force is applied to the semiconductor package of FIG. 21.

As illustrated in FIGS. 21 and 22, the semiconductor package includes a first substrate 411, a first semiconductor chip 421, and an encapsulation member 430.

The first semiconductor chip 421 is disposed on the first substrate 411, and the first substrate 411 is electrically connected with the first semiconductor chip 421 so that the first substrate 411 delivers an electrical signal generated by the first semiconductor chip 421 to an outer device.

The first semiconductor chip 421 may be fabricated via a semiconductor process such that the first semiconductor chip 421 is disposed on the first substrate 411, and is electrically connected with the first substrate 411 by direct contact with the first substrate 411.

The encapsulation member 430 electrically protects the first semiconductor chip 421 by covering the first semiconductor chip 421 so as to maintain characteristics of the electrical signal generated by the first semiconductor chip 421. As described above, the encapsulation member 430 also physically protects the first semiconductor chip 421 from various external forces and/or foreign substances. The encapsulation member 430 includes, for example, a thermocurable resin that is an insulating material, that can be thermally formed, and that is hardened after being thermally formed. As a result, the encapsulation member 430 firmly protects the first semiconductor chip 421.

As illustrated in FIGS. 21 and 22, the first substrate 411 includes one or more grooves 412 and 413 formed from the top surface of the first substrate 411 so as to induce deformation in response to external forces F1, F2, and F3, or external forces F4, F5, and F6.

As illustrated in FIG. 21, when bend deformation as denoted by the dashed lines in FIG. 21 occurs in the semiconductor package due to the external forces F1, F2, and F3, entrances of the grooves 412 and 413 widen so that the deformation of the first substrate 411 due to the external forces F1, F2, and F3 may be facilitated.

As a result, by making the first substrate 411 more flexible, total or partial damage to the first substrate 411 due to external forces may be prevented.

Also, it is possible to actively induce the bend deformation due to the external forces F1, F2, and F3 to be localized to the grooves 412 and 413 that are relatively less important parts, not including functioning/essential components of the semiconductor package.

In other words, by inducing the deformation to occur in the grooves 412 and 413, it is possible to prevent parts, including, for example, the first semiconductor chip 421 or a signal connecting member, from deforming.

Therefore, it is possible to make the first substrate 411 more flexible in response to various external forces or shocks by using the grooves 412 and 413, and to induce the deformation of weaker parts in the grooves 412 and 413.

Also, referring to FIG. 22, a backward-bend as denoted by the dashed lines in FIG. 22, occurs in a semiconductor package due to the external forces F4, F5, and F6 which are in a reverse direction with respect to the external forces F1, F2, and F3. As shown in FIG. 22, the entrances of the grooves 412 and 413 narrow so that deformation of the first substrate 411 due to the external forces F4, F5, and F6 may be further facilitated, and it is possible to further control a location of the deformation.

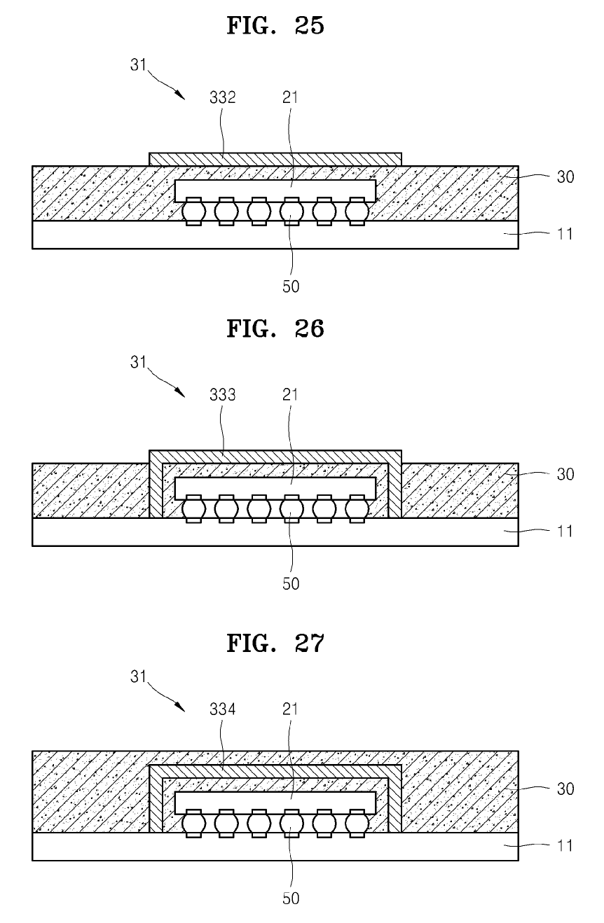

FIGS. 23 through 29 are each cross-sectional views of a semiconductor package according to embodiments of the inventive concept. As illustrated in FIG. 23, a stress mitigation unit 31 includes one or more blocking protrusions 330 formed around a first semiconductor chip 21. As illustrated in FIG. 23, the blocking protrusions 330 may be formed of the same material as an encapsulation member 30, or as illustrated in FIGS. 24 through 26, the blocking protrusions 331, 332, and 333 are formed of a material different from that of an encapsulation member 30.

The material of the blocking protrusions 331, 332, and 333 may have elasticity and may include, for example, a rubber, a resin, urethane, silicone, a polymer material, plastic, STYROFOAM, or the like, or instead, may include steel materials, such as metal, ceramic, engineering plastic, or the like, which are rigid. Thus, due to the blocking protrusions 330, 331, 332, and 333, the stress mitigation unit 31 mitigates or blocks stress from around the first semiconductor chip 21 to the first semiconductor chip 21. The blocking protrusions 331 and 332 are adhered on a surface of the encapsulation member 30, and the blocking protrusion 333 are formed by forming perforations in the encapsulation member 30 and then the material forming the blocking protrusion 333 is inserted into the perforations.

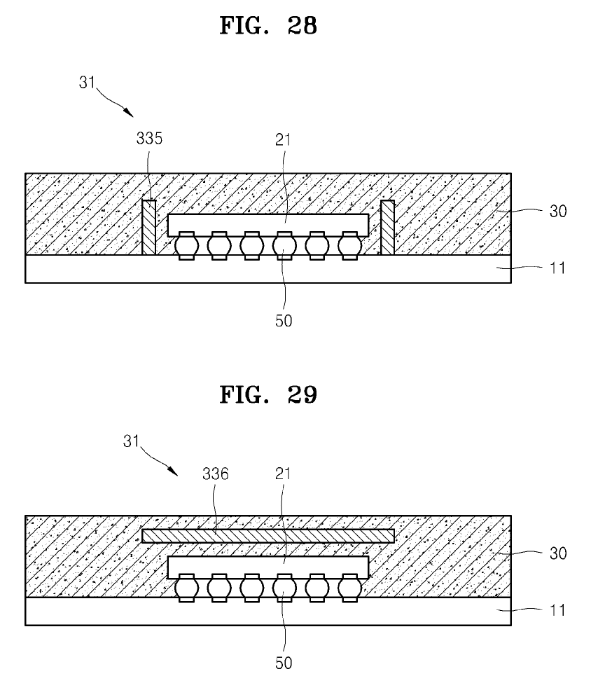

As illustrated in FIGS. 27-29, the stress mitigation unit 31 includes one or more blocking walls 334, 335, and 336 that protect the first semiconductor chip 21 by surrounding the first semiconductor chip 21. As illustrated in FIG. 27, the blocking wall 334 are formed in the encapsulation member 30 so as to surround both an upper area and side areas of the first semiconductor chip 21. As illustrated in FIG. 28, the blocking wall 335 is formed in the encapsulation member 30 so as to surround only side areas of the first semiconductor chip 21, or as illustrated in FIG. 29, the blocking wall 336 is formed in the encapsulation member 30 so as to surround only an upper area of the first semiconductor chip 21.

A material of the blocking walls 334, 335, and 336 may have elasticity and may include, for example, a rubber, a resin, urethane, silicone, a polymer material, plastic, STYROFOAM, or the like, or instead, may include steel materials, such as metal, ceramic, engineering plastic, or the like, which are rigid. Due to the blocking walls 334, 335, and 336, the stress mitigation unit 31 may mitigate or block stress areas around the first semiconductor chip 21 to the first semiconductor chip 21. In order to form the blocking walls 334, 335, and 336, one of various methods may be used, including, for example, a double injection mold method by which a groove is first formed using a first injection mold and then an opening is sealed using a second injection mold.

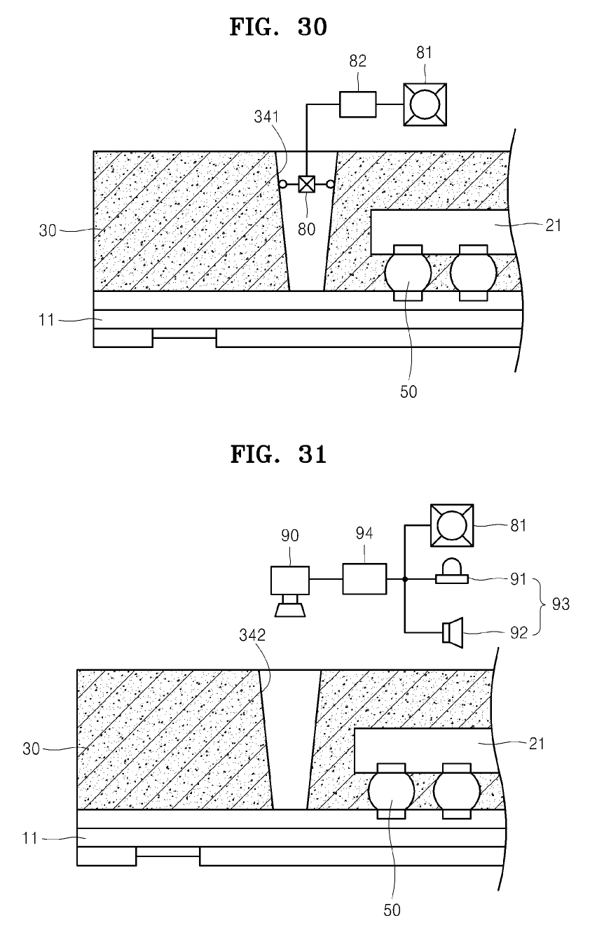

FIGS. 30 and 31 are magnified cross-sectional views of test systems of a semiconductor package, according to embodiments of the inventive concept.

As illustrated in FIG. 30, the semiconductor package includes a first substrate 11, a first semiconductor chip 21 disposed on the first substrate 11, and an encapsulation member 30 that protects the first semiconductor chip 21 by covering the first semiconductor chip 21 and that includes a groove 341 for inducing deformation. The test system includes a change detection sensor 80, which is a type of testing device for detecting a change of the groove 341, such as, for example, a change in the dimensions of or area in the groove, and a control unit 82 that receives a change signal from the change detection sensor 80, transforms the change signal into a stress value, and outputs a control signal by which the stress value is displayed on a display device 81.

Thus, an operator may produce and check concrete values corresponding to the stress values generated in the semiconductor package, so that the operator may take necessary measures to prevent generation of a defective product.

As illustrated in FIG. 31, the test system of the semiconductor package includes a camera 90, which is a type of testing device for photographing the groove 342 to detect, for example, a change in the dimensions of or area in the groove, and a control unit 94 that receives an image signal from the camera 90, compares the image signal with a reference value, and when a value of the image signal, for example, exceeds the reference value, outputs a warning signal to a display device 81 or to a warning device 93 including, for example a warning-light device 91 or a warning-sound device 92. Thus, an abnormal status of the groove 342 may be detected via the camera 90 in a semiconductor production line, so that a defective product or a product potentially having a defect may be promptly detected in real-time.

While the inventive concept has been particularly shown and described with reference to exemplary embodiments thereof, it will be understood that various changes in form and details may be made therein without departing from the spirit and scope as set forth in the following claims.

What is claimed is:

1. A semiconductor device comprising:
a first substrate;
a first semiconductor chip on the first substrate;
an encapsulation member on the first substrate and covering the first semiconductor chip; and
at least one groove formed in the encapsulation member.

2. The semiconductor device of claim 1, wherein the groove penetrates through the encapsulation member from a surface of the encapsulation member to the first substrate.

3. The semiconductor device of claim 1, wherein the groove partially penetrates the encapsulation member from a surface of the encapsulation member into an upper portion of the encapsulation member.

4. The semiconductor device of claim 1, wherein the groove comprises a slope, wherein a diameter of the groove decreases in a direction from a surface of the encapsulation member to the first substrate.

5. The semiconductor device of claim 1, wherein the groove is not formed over an upper surface of the first semiconductor chip.

6. The semiconductor device of claim 1, wherein the groove is spaced apart from and surrounds the first semiconductor chip.

7. The semiconductor device of claim 1, wherein the groove is formed in a side surface of the encapsulation member.

8. The semiconductor device of claim 1, wherein the groove is formed at an interface between the encapsulation member and the first substrate.

9. The semiconductor device of claim 1, wherein the entire groove is formed in an inner portion of the encapsulation member.

10. The semiconductor device of claim 1, wherein a filling material fills the groove.

11. The semiconductor device of claim 1, further comprising:
a second substrate electrically contacting the first substrate; and
a second semiconductor chip formed on the second substrate.

12. The semiconductor device of claim 11, wherein a Through Mold Via (TMV) is formed in the encapsulation member to electrically connect the first substrate and the second substrate.

13. The semiconductor device of claim 1, wherein the encapsulation member comprises an inner encapsulation member covering the first semiconductor chip, and an inner substrate whereon the first semiconductor chip is formed.

14. A test system of a semiconductor package apparatus comprising a substrate, a semiconductor chip on the substrate, an encapsulation member on the substrate and covering the semiconductor chip, and a stress mitigation unit formed in the encapsulation member, the test system comprising:
a testing device detecting a deformation of the stress mitigation unit.

15. A semiconductor device comprising:
a first substrate;
a first semiconductor chip including one or more bumps formed on a bottom surface of the first semiconductor chip and contacting the first substrate;
an encapsulation member on the first substrate and covering the first semiconductor chip; and
a stress mitigation member including at least one groove formed in the encapsulation member.

16. The semiconductor device of claim 15, wherein the groove penetrates through the encapsulation member from a surface of the encapsulation member to the first substrate.

17. The semiconductor device of claim 15, wherein the groove partially penetrates the encapsulation member from a surface of the encapsulation member into an upper portion of the encapsulation member.

18. The semiconductor device of claim 15, wherein the groove comprises a slope, wherein a diameter of the groove decreases in a direction from a surface of the encapsulation member to the first substrate.

19. The semiconductor device of claim 15, wherein the groove is spaced apart from and surrounds at least part of the first semiconductor chip.

20. The semiconductor device of claim 15, wherein the groove is formed in a side surface of the encapsulation member.
